(19) United States
(12) Patent Application Publication
(10) Pub. No.: US 2012/0202352 A1
(43) Pub. Date: Aug. 9, 2012

(54) METHOD OF AND APPARATUS FOR MANUFACTURING SEMICONDUCTOR DEVICE

(75) Inventor: Mikio TAKAGI, Kawasaki-shi (JP)

(73) Assignee: F.T.L. CO., LTD., Kawasaki-shi (JP)

(21) Appl. No.: 13/450,670

(22) Filed: Apr. 19, 2012

Related U.S. Application Data
(63) Continuation of application No. 12/509,867, filed on Jul. 27, 2009, now abandoned.
Application No. 12/509,867 is a continuation of application No. 10/401,591, filed on Mar. 31, 2003, now abandoned.

(30) Foreign Application Priority Data
Apr. 1, 2002 (JP) 2002-98317

(51) Int. Cl. H01L 21/30; C23C 16/46

(52) U.S. Cl. 438/758; 118/725; 257/E21.211

(57) ABSTRACT

A vertical single wall reaction tube type batch processing furnace can reduce the generation of particles. A method of removing native oxide film by fluoride gas can enhance the efficiency of utilization of gas. A method of exciting reaction gas by a catalyst at high temperature can be applied to a batch processing. A method of exciting reaction gas by a catalyst utilizes an oxidizing agent and gas other than an oxidizing agent. The flow rate of gas in the gas injection pipe and that of gas in the exhaust pipe are made to be substantially equal to each other. The gap between two adjacent wafers is made greater than the mean free path of gas. The oxidizing agent is dissociated by a catalyst of Ir, V or Kanthal while the gas other than the oxidizing agent is dissociated by a catalyst of W.

### BACKGROUND OF THE INVENTION

1. Field of the Invention

The present invention relates to a method of and an apparatus for manufacturing a semiconductor device. More particularly, the method of manufacturing a semiconductor device according to the invention is applicable to a low pressure CVD (chemical vapor deposition) for example SiN, SiO₂, amorphous Si, poly-Si or the like, etching, ashing of resist and cleaning of a reaction tube. In the description the wording “etching” refers to dry cleaning for removing the native oxide film formed on the silicon exposed in a contact hole for burying an electrode material such as poly-Si, doped poly-Si, SiO₂, SiN, SiON, TiSi₂, WSi₂ or TiN, or the scum generated by reaction of the resist and silicon.

2. Related Background Art

Vertical batch type heating furnaces include the hot wall type and the cold wall type. Hot wall type furnaces are described in Kazuo Maeda: “Beginner's Book 3: The Semiconductor Manufacturing System for Beginners”, Industrial Research Society, Jul. 5, 1999, 1st ed., 3rd plate, p. 125. Cold wall type furnaces are described in p. 143 of the same book.

Initially, vertical type heating furnaces were designed to use a single wall reaction tube. However, as elimination of particles was rigorously required, double wall reaction tubes came into the scene so as to draw reaction gas from the annular gap to an exhaust port (“Vertical type CVD System ERECTUS”; ‘Electronic Materials’, March, 1986, SC-6, pp. 98-102).

The growth conditions in a hot wall double tube type vertical furnace as described for the prior art in U.S. Pat. No. 6,204,194 (Mar. 20, 2001), which was assigned to the applicant of the present patent application, include the number of wafers: 100 to 150, wafer intervals: 5 to 9 mm, flat zone length: 700 to 900 mm, intra-furnace pressure: 0.3 to 1 torr (40 to 133 Pa) and flow rate of introducing reaction gas into furnace: 3 to 7 m/sec (col. 1, 11. 34-43). In such a CVD condition of the prior art, a part of the reaction gas flowing vertically in the reaction tube is engulfed in surfaces from the peripheries of the wafers and hence the growth rate is restricted by the engulfment of the gas, which makes the growth rate slow. Therefore, in the above cited U.S. patent, a high-speed growth CVD is achieved by injecting the reaction gas in parallel with the surfaces of the wafers arranged vertically in the vertical batch processing heating furnace using a single wall reaction tube. In terms of reaction kinetics, under the condition of high temperature as diffusion rate-determining, all the reaction gas is injected at high speed in parallel with the wafer surfaces in order to accelerate a diffusion.

WO01/173832 Publication, which was applied by the applicant of the present patent application, proposes an improvement to a method of removing the native oxide film in a contact hole by means of etching gas that is excited by a microwave.

With the method described in the above cited patent document, the native oxide film, which is SiO₂ film, in a contact hole is removed typically by etching to 5 to 20 angstroms. SiO₂ is transformed into complex Si₆(NH₄), which can easily be decomposed and evaporated at low temperature. It is known that the complex producing reaction shows a high reaction rate at temperature between 10 and 25° C. but stops at 60° C.

U.S. Pat. No. 4,237,150, proposes a method of dissociating silane into atomic hydrogen and carbon and forming hydrogenated amorphous silicon film by heating silane at 1,400˜1,600° C. in vacuum of 10⁻⁶ to 10⁻⁴ torr by means of tungsten or carbon foil.

A method of utilizing a hot heating medium (to be referred to as “hot gas dissociation method” hereinafter) similar to the one disclosed in the above quoted U.S. Pat. No. 4,237,150 is reported by Nishimura et. al of Japan Advanced Institute of Science and Technology in “The Bulletin of the Japan Society of Applied Physics”, Aut., 2001, 13P-P11. According to the report, the dissociation/utilization efficiency of reaction gas is high because such a heating medium has a catalytic effect. This method is also introduced to the public by Asahi Shinbun (newspaper) evening issue of Jan. 16, 2002, in an article entitled “Light for Reestablishing the Country by Electronics”. The method is referred to as “Catalytic chemical vapor phase growth method” in the article.

It is said that, with a hot gas dissociation method, gas molecules are dissociated at a certain probability and seeds that are in some form or another are chemically adsorbed to the catalyst surface so that dissociation/adsorption seeds are thermally desorbed by the hot catalyst and emitted into the reaction space (The Achievement Reporting Session Document for Semiconductor Device Manufacturing Processes Using Cat-CVD Methods, Jun. 4, 2001, p. 15). For SiH₄ and W catalysts, for instance, the term “hot” refers to 1,600° C. or above. Generally, the frequency of collision of a gas molecule with a solid surface is a function of the density (ng) of gas molecules. However, since the chemical formulas of dissociation/adsorption seeds are unknown, the frequency of collision of an SiH₄ molecule in the reaction space is calculated by using the molecule density of SiH₄ and the actual result of CVD is observed in the above cited document.

With the method disclosed in the above cited U.S. Pat. No. 6,204,194, reaction gas is made to flow upward in the injection pipe and subsequently injected at high speed into the gap between the opposite surfaces of wafers by way of a large number of injection holes arranged at the lateral wall of the injection pipe. The flow rate of reaction gas is maximized when it passes through the injection holes. FIG. 1 of the accompanying drawings schematically illustrates the gas flow rate of this method. More specifically, FIG. 1 shows the gas flow rate relative to a horizontal position (horizontal axis) in a vertical reaction tube. While reaction gas is injected from the injection holes at high speed (see dotted line in FIG. 1), it is heated by a heater to produce particles, which are then blown into the reaction space to give rise to defects in the wafers, because reaction gas is driven to flow in the injection pipe at a relatively low rate.

Therefore, the first object of the present invention is to provide a low pressure CVD method using a vertical batch type heating furnace that can reduce the production of particles.

With the microwave-excited dry etching method, a microwave generator is arranged around a pipe made of Al₂O₃ and/or SiO₂ and H₂, N₂, NF, or NF₃+NH₃ is forced to flow through the pipe and excited by a microwave to produce etching gas of active seeds, which is then used for reaction. With this method, a microwave is not irradiated to NF₃ from the anti-particle point of view. Therefore, it reacts with microwave-excited H₂ so as to be transformed into active seeds showing a strong etching effect in order to remove native oxide film. However, it secondarily reacts with Al₂O₃ and SiO₂. Al and Si are produced to give rise to particles as a result of the secondary reaction. Additionally, a large volume of NF₃ is required with this method because NF₃ that is to be activated is not directly excited by a microwave.

Therefore, the second object of the present invention is to provide a method of removing native oxide film by producing a complex that can reduce the rate of consumption of gas containing halogen atoms.

While a hot gas dissociation method is attracting attention because it can be applied to large surface area wafers and involves a cold process, it is basically used with a single wafer system and no batch system has been realized for it to date. Therefore, the third object of the present invention is to provide a batch type hot gas dissociation system.

Furthermore, when dissociating an oxidizing agent by means of a hot gas dissociation method, a fierce reaction takes place on the catalyst to give rise to a problem of degrading the catalyst. Therefore, the fourth object of the present invention is to provide a batch type hot gas dissociation system that can produce oxide film.

### SUMMARY OF THE INVENTION

According to the invention, the first object is achieved by providing a semiconductor device manufacturing method using a low pressure CVD to dissolve the particle problem, the method comprising: flatly laying two or more than two semiconductor substrates one above another substantially at regular intervals in a single wall reaction tube surrounding the lateral sides of a substrate holding jig and closed at the top so as to be able to remove substrates from the jig, the substrates including or not including dummy wafers; arranging the semiconductor substrates in a vertical type heating furnace provided with a heating means; and bringing the semiconductor substrates into contact with processing gas; the flow rate of gas flowing through a gas injection pipe extending vertically between the single wall reaction tube and the substrate holding jig and the flow rate of gas flowing through a gas exhaust pipe extending vertically between the single wall reaction tube and the substrate holding jig being made substantially equal to each other.

Referring to FIG. 1, the gas flow rates of gases flowing through the respective tubes are made to show a relationship of V₂′>>V₁′ with conventional methods but V₂≈V₁ according to the present invention. Although the relationship tends to be V₂>V₁ under the influence of the exhaust pump, the difference is preferably not greater than five times. The gas flow rates increase as the gap separating wafers is reduced (see dotted lines (1) and (2)).

Particles can be reduced by raising the gas flow rates of gases flowing through wafers when the relationship of V₂≈V₁ is established because the reaction rate is raised for the reason of the principle described in the above cited U.S. Pat. No. 6,204,194.

The second and third objects of the invention are achieved by providing a hot gas dissociation system comprising: a substrate holding jig adapted to removably arranging two or more than two semiconductor substrates substantially at regular intervals greater than the mean free path of gas in a reaction tube, the substrates including or not including dummy wafers; a heating means attached, if necessary, to the reaction tube in order to heat the semiconductor substrates; a gas injection means for injecting gas into the reaction tube; an exhaust means for exhausting gas to the outside of the reaction tube; and a heating/catalyzing means for dissociating gas before or after injecting gas from the injection means.

Note that gas to be used in a hot gas dissociation system in order to achieve the second object includes halogen-containing gas for removing native oxide film.

The fourth object of the invention is achieved by providing a hot gas dissociation system comprising: a substrate holding jig adapted to removably arranging one or more than one semiconductor substrates in a reaction tube, the substrates including or not including dummy wafers; a heating means attached, if necessary, to the reaction tube in order to heat the semiconductor substrate; a first gas injection means for injecting a first gas other than an oxidizing agent into the reaction tube; a first heating/catalyzing means for dissociating the first gas before or after injecting gas from the gas injection means; a second gas injection means for injecting a second gas of an oxidizing agent into the reaction tube; a second heating/catalyzing means of iridium, vanadium or an Fe—Cr—Al type electric resistor alloy for dissociating the second gas before or after injecting gas from the first gas injecting means; and an exhaust means for exhausting the first and second gases to the outside of the reaction tube; the first gas injection means and the second gas injection means being oriented so as to cause the first and second gases to be mixed with each other after dissociation by the respective catalysts.

There are various different modes of realization for the gas injection means and the exhaust means to be used for a low pressure CVD method according to the invention.

For instance, the gas injection means may be a pipe extending vertically in the reaction tube and provided at the lateral wall thereof with injection holes and the exhaust means may be a pipe extending vertically in the reaction tube and provided at the lateral wall thereof with suction holes. In this case, the substrate holding jig holds semiconductor substrates that are flatly stacked in the furnace.

In another mode of realization, the gas injection means has an opening at a lower part of the reaction tube and the exhaust means is an annular gap formed between the reaction tube and an outer tube coaxially surrounding the reaction tube. In this mode of realization, the exhaust gas flow path formed by utilizing the annular gap can be made to show a large gas conductance.

In still another mode of realization, the gas injection means is a pipe having an opening at the lateral wall of the reaction tube and the gas exhaust means is an exhaust pipe having an opening at the lateral wall of the reaction tube. In this mode of realization, it is preferable that the vertical position of the gas injection pipe and that of the exhaust pipe substantially agree with each other.

Additionally, there are various mode of realization for the heating/catalyzing means that is used to achieve any of the second through fourth objects of the invention. For instance, the heating/catalyzing means may be arranged to face the injection holes in the reaction tube. In this mode of realization, a heat shield plate is preferably arranged between the heating/catalyzing means and the semiconductor substrates. In another mode of realization, the heating/catalyzing means may be arranged in the gas injection pipe.

No heating means such as heater or lamp is required for a hot gas dissociation system according to the invention where the system is applied to an etching or an ashing of resists because dissociated gas heats wafers to 200 to 300° C. However, in the other application a heating means such as heater or lamp may be provided by referring to the heating temperature, which will be described hereinafter.

The mean free path (λ) of gas that is innegligible to achieve the second and third objects of the present invention is expressed by the formula shown below;

λ∝T/d species²·Pg,

where T represents temperature (K), d species represents the gas diameter (m) and Pg represents the gas pressure (Pa).

The mean free path (cm) of hydrogen (d species=2.75×10⁻¹⁰) and that of silane (d species=m) are shown in the table below.

TABLE 1

Pg = 0.1 Torr (13.3 Pa)

| Tg | H₂ | SiH₄ |
|---|---|---|
| 0° C. (cm) | 0.084 | 0.0106 |
| 2000° C. (cm) | 0.70 | 0.0878 |

The hot gas dissociation method shows a high gas utilization efficiency if compared with the plasma CVD method. This means that the collision frequency (ncol) of gas molecules with substrates is high. The collision frequency (ncol) of gas molecules with a plurality of wafers needs to be uniform for uniformly forming film on the wafers.

FIGS. 2A and 2B schematically illustrate collisions of gas molecules with a pair of substrates. FIG. 2A shows an instance where the gap (d₁) separating the wafers<the mean free path (λ), whereas FIG. 2B shows an instance where the gap (d₂) separating the wafers>the mean free path (λ). The probability that gas molecules collide with each other before they collide with either of the substrates is higher in the case of FIG. 2A than in the case of FIG. 2B. The instance of FIG. 2A is not desirable because the collision frequency of gas molecules with the substrates is uneven and molecules easily regain a ground state from an active state. Although the phenomenon of FIGS. 2A and 2B can take place with plasma CVD, it appears more remarkably with a hot gas dissociation method. For the above described reason, in a hot gas dissociation system according to the invention, the gap separating wafers is made not smaller than the mean free path (λ) of gas (d>λ). However, d>>λ is not senseless because it requires a huge reaction space. Therefore, it is preferable that d=1 to 3λ.

Gas that is to be dissociated by the heating/catalyzing means is selected from substances other than oxidizing agents. Examples of such substances include SiH₄, Si₂H₆, SiH₂Cl₂, TEOS, TMOP, NH₃, PH₃, B₂H₆, H₂, N₂, Cl₂, F, SiCl₄, BBr, AsH₃, PCl₃, WF₆, TiCl₃, SiCl₄, GeCl₄, NF₃, SF₆ and CF₃. They also include TEOS containing oxygen in the compound. Oxidizing agents such as NO₂, O₂, CO₂ and O₃ as well as O₂ and O₃ gases that are excited by a high frequency wave of 2.5 GHz, for instance, (also referred to as remote plasma gas) are not dissociated and the third mode of carrying out the present invention as defined in claim 9 is provided with a separate injection means for injecting such an oxidizing agent.

Unlike the arrangement of claim 9, in a semiconductor device manufacturing system for achieving the fourth object of the invention, iridium, vanadium or an Fe—Cr—Al type electric resistor alloy, which is well known as Kanthal, is used as oxidizing agent heating/catalyzing means in order to prevent the heater from degrading.

Gases that can be used for the purpose of the present invention will be described further.

Gases that can be used to achieve the first object of the invention include those well known in the field of CVD and diffusion.

Gases that can be used to achieve the third object of the invention and their reaction temperatures are listed below.

(a) combination of Si₃N₄ film: SiH₄ and NH₃ (reaction temperature: 750 to 800° C.), combination of SiH₂Cl₂ and NH₃ (reaction temperature: 750 to 800° C.)

(b) poly-Si film: SiH₄ (580 to 625° C.), Si₂H₆ (500 to 550° C.)

(c) combination of p-doped poly-Si film: SiH₄ and PH₃ (550 to 600° C.)

For forming oxide film to achieve the third object of the invention, the oxidizing agent is not dissociated by a W heater and is made to react with dissociation gas such as SiH₄. However, TEOS that contains oxygen in the compound is dissociated by a W heater. To achieve the fourth object of the invention, the oxidizing agent is dissociated by an iridium heater. The oxidizing agent can be selected from a group including NO₂, O₂, CO₂ and O₃. Particularly preferable combinations are listed below.

(d) SiO₂ film: SiH₄ and NO₂ (about 800° C.), SiH₄ and O₂ (300 to 400° C.), SiH₄ and CO₂ (900 to 1,000° C.), TEOS and O₂ (650 to 670° C.), TEOS (300 to 400° C.), TEOS and O₃ (350 to 400° C.)

(e) combination of SiON film: SiH₂Cl₂, NH₃ and O₂ (700 to 800° C.)

### BRIEF DESCRIPTION OF THE DRAWINGS

FIG. 1 is a schematic illustration of gas flow rate of a method according to the present invention and a conventional method;

FIGS. 2A and 2B are schematic illustrations of gas molecules moving between a pair of substrates;

FIG. 3 is a schematic cross sectional view of a batch processing vertical furnace of the single wall tube type to be used with the first method according to the present invention;

FIG. 4 is a schematic cross sectional plan view taken along and viewed in the direction of arrows A-A in FIG. 3;

FIGS. 5A, 5B and 5C are respectively a longitudinal view and front views of a reaction gas injection pipe that can be used for the purpose of the invention;

FIG. 6 is a schematic cross sectional view of a heating/catalyzing means that can be used for the second through fourth inventions;

FIG. 7 is a schematic cross sectional view of another heating/catalyzing means;

FIG. 8 is a schematic cross sectional view of still another heating/catalyzing means;

FIG. 9 is a schematic longitudinal cross sectional view of a lamp heater that can be used for the purpose of the invention;

FIG. 10 is a schematic cross sectional view taken along and viewed in the direction of arrows E-E in FIG. 9;

FIG. 11 is a schematic view of another embodiment of semiconductor device manufacturing system realized to achieve the second object of the invention;

FIG. 12 is a schematic view of the hot gas dissociation system of the embodiment of FIG. 11;

FIG. 13 is a schematic cross sectional view taken along and viewed in the direction of arrows A-A in FIG. 11;

FIG. 14 is a schematic view of another system realized to achieve the fourth object of the invention;

FIG. 15 is a schematic cross sectional plan view of a system realized to achieve the third and fourth objects of the invention; and

FIG. 16 is a schematic longitudinal cross sectional view of the system of FIG. 15.

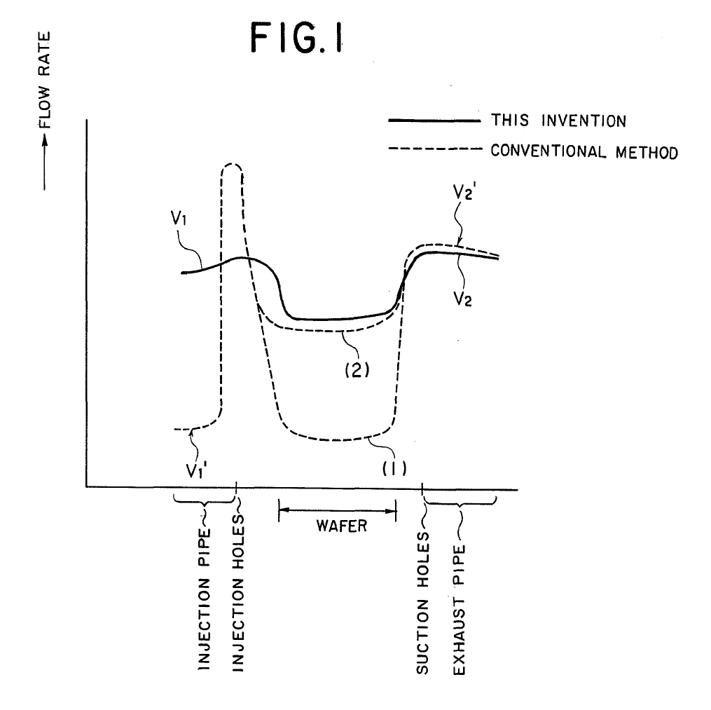

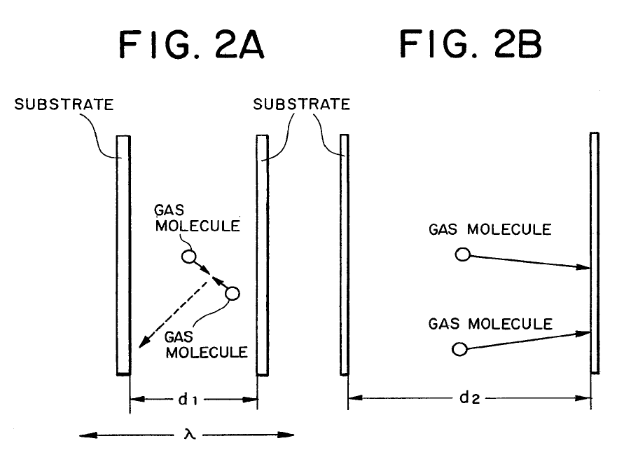

### DESCRIPTION OF THE PREFERRED EMBODIMENTS

Now, the present invention will be described in greater detail by referring to the accompanying drawings that illustrate preferred embodiments of the present invention.

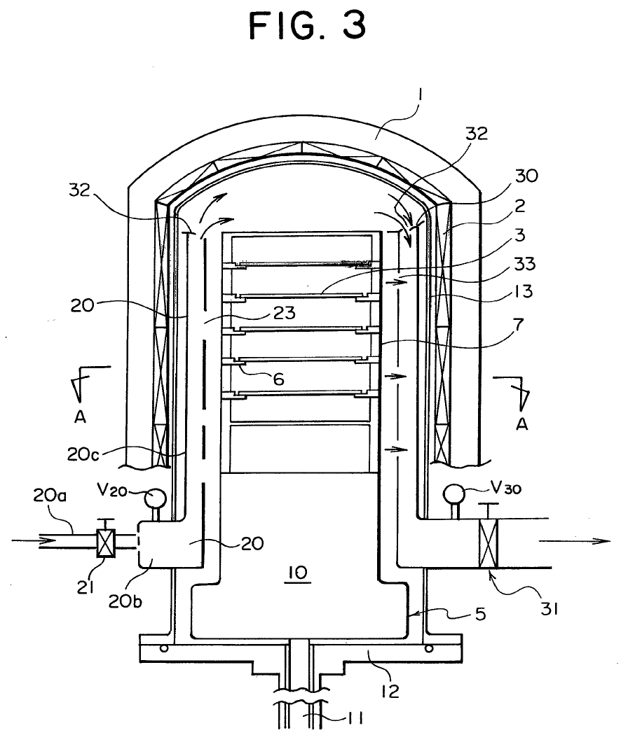

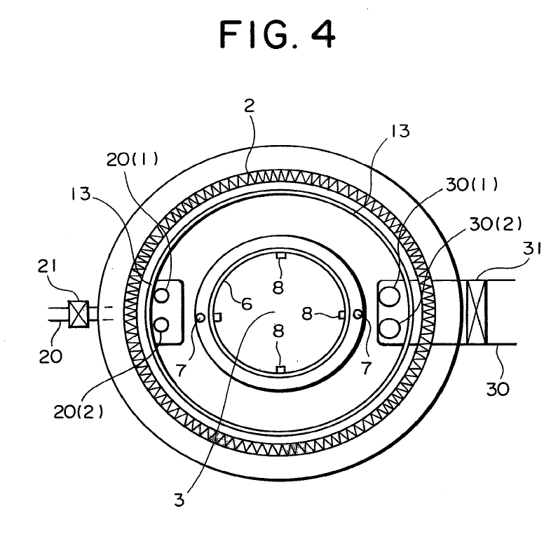

FIGS. 3 and 4 schematically illustrate a system for carrying out the first method of the present invention. Referring to FIGS. 3 and 4, reference symbol 1 denotes the furnace body of a vertical type heating furnace. It is made of fire-resistant and heat-resistant materials and shows a pot-like profile specific to a hot wall furnace closed at the top and open at the bottom. Reference symbol 2 denotes a heating means, or heater, rigidly secured to the inner wall of the furnace body 1 by means of an appropriate jig. The heater 2 is divided into a number of zones, the electric currents supplied to the respective zones are controlled independently. Although not illustrated in detail, current meters V₂₀, V₃₀ are arranged at lower positions of the furnace body 1 and the heater 2.

Reference symbol 5 denotes a tower type substrate holding jig that is entirely supported by a lower center shaft 11 so as to be vertically movable and rotatable in the furnace space. The substrate holding jig 5 needs to be rotated when the processing temperature is not higher than 150° C. When the processing temperature is between 350 and 450° C., it is possible to achieve an intra-planar thickness distribution of 5 to 10% without rotating the jig 5. Reference symbol 3 denotes wafers. One or more than one top wafers and/or one or more than one bottom wafers may be dummy wafers. The gap separating two adjacently located wafers is preferably 5 to 15 mm, more preferably about 10 mm, for 8-inch wafers. A number of annular sections 6 are stacked at regular intervals and rigidly secured to a support column 7 in order to vertically arrange and support wafers 3. Each annular section 6 is provided with four claws 8 that are arranged at regular intervals of 90° and projecting horizontally toward the central axis of the furnace to hold the peripheral edge of a wafer 3.

Reference symbol 10 denotes a base section for rigidly securing the bottom end of the support column 7. The base section 10 may be a hollow body containing vacuum in the inside. The lower center shaft 11 rigidly fitted to the bottom of the base section 10 is linked to a lifting/rotating mechanism (not shown) through a removable center hole of a bottom plate 12.

Reference symbol 13 denotes a quartz-made single wall type reaction tube (to be referred to simply as “reaction tube” hereinafter). A reaction space is provided in the inside. Reference symbol 20 denotes a reaction gas injection pipe and reference symbol 30 denotes reaction gas exhaust pipe. The reaction gas injection pipe 20 is provided with a pair of pipe bodies and the reaction gas exhaust pipe 30 is also provided with a pair of pipe bodies.

The reaction gas injection pipe 20 preferably has an inner diameter not less than 10 mm. Each pipe body of the reaction gas injection pipe 20 has an introducing section 20a, a low pressure section 20b and an injecting section 20c that are arranged continuously in the mentioned order. The introducing section 20a is provided with a valve 21 to block any inflow of reaction gas after the end of reaction. During a CVD growth period, the valves 21 of the reaction gas injection pipe 20 is operated so as to be opened and closed to define the conductance in the furnace corresponding to the capacity of the pumps arranged in the reaction gas exhaust pipe 30. The next low pressure section 20b is located off a red-hot region and adapted to reduce the internal pressure and increase the gas flow rate so as to realize a condition of V₂≈V₁ as the inner diameter of the tube is rapidly increased there.

Finally, the injecting section 20c extends vertically in the furnace so as to uniformly deliver reaction gas to the stacked wafers 3 in the furnace through injection holes 23. Some different modes of realizing injection holes 23 will be discussed below.

For instance, the front end of the reaction gas injection pipe 20 is closed and reaction gas is injected through the injection holes arranged at the lateral wall of the pipe. In this mode, the total cross sectional area (S₁) of the injection holes 23 is made greater than the cross section area (S₂) of the reaction gas injection pipe 20C (S₁>S₂) in order to avoid any increase in the gas flow rate due to compressed gas because the inside of a single wall type reaction tube 13 is located closer to the exhaust pump than to the inside of the reaction gas injection pipe 20 and hence the flow rate of reaction gas tends to increase in the single wall type reaction tube 13.

In another mode, the front end of the reaction gas injection pipe 20 is not closed but made to be an open end 32 (FIG. 3). Since the cross sectional area (S₁′) of the open end 32 provides an effect same as the cross sectional area (S₁) of the injection holes, any increase in the gas flow rate due to compressed gas can be avoided when S₁+S₁′>S₂. The value of the left side of the formula can be increased when the front end of the reaction gas injection pipe is broadened.

In still another mode, the front end of the reaction gas injection pipe 20 is made to be an open end 32 and all the injection holes 23 are closed. Thus, in this mode, reaction gas is injected from the open end 32.

The reaction gas exhaust pipe 30 is an L-shaped pipe provided at the exit side thereof with a valve 31 and at the front end thereof with a suction hole 32. It is also provided at the lateral wall thereof with suction holes 33 and is connected to an exhaust pump (not shown).

Current meters V₂₀, V₃₀ are arranged at corresponding positions of the reaction gas injection pipe 20 and the reaction gas exhaust pipe 30 to gauge the respective gas flow rates.

As shown in FIG. 4, a pair of pipe bodies 20₍₁₎, 20₍₂₎ may be arranged side by side for the reaction gas injection pipe 20. The pipe bodies 20₍ⱼ₎, 20₍₂₎ may have a same length or different respective lengths. Then, different types of gas may be made to flow through the respective pipe bodies 20₍₁₎, 20₍₂₎ having a same length. Reaction gas can be made to flow only to upper wafer(s) or lower wafer(s) by means of pipe bodies 20₍₁₎, 20₍₂₎ having different respective lengths.

Similarly, a pair of pipe bodies 30₍₁₎, 30₍₂₎ may be arranged side by side for the reaction gas exhaust pipe 30.

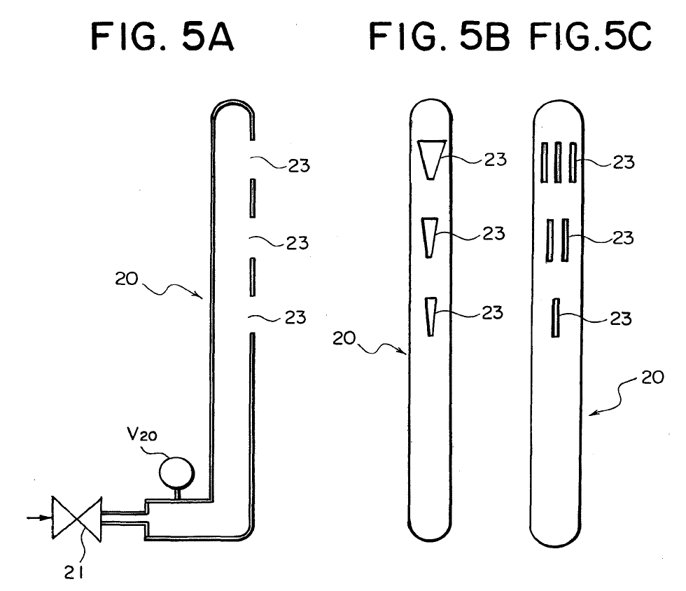

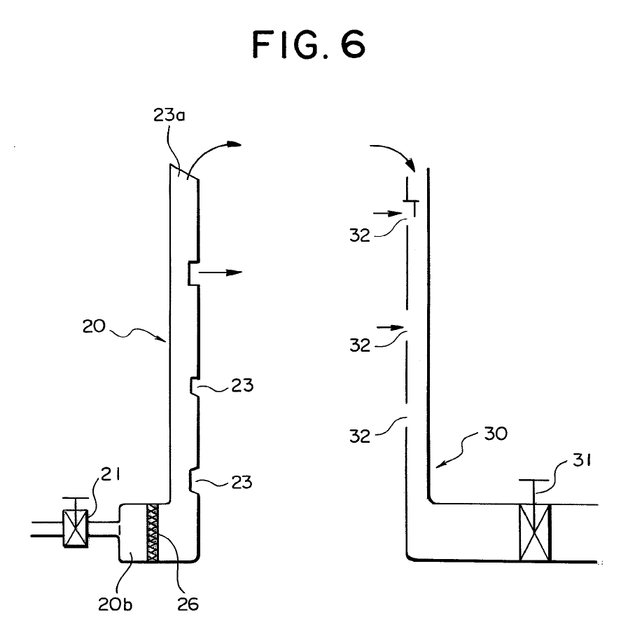

FIGS. 5A through 5C illustrate a reaction gas injection pipe 20 whose front end is closed.

FIG. 5A is a cross sectional view and FIGS. 5B and 5C are front views of different reaction gas injection pipes 20. As shown in FIG. 5B, three injection holes 23 have different cross sectional areas with the (upper) one located close to the front end having a large triangular cross section and the (lower) one located close to the rear end having a small triangular cross section. Each injection hole 23 shows an inverted triangular contour and hence has a larger area in an upper section and smaller area in a lower section. With such differentiated contours of the holes, the reaction gas injection holes can be made to inject reaction gas at a same flow rate regardless of their vertical positions. The same effect is achieved by arranging injection holes 23 having a same contour and a same size in a manner as shown in FIG. 5C.

FIG. 6 is a schematic cross sectional view of a vertical batch processing heating furnace similar to the one shown in FIG. 3 but shows only the reaction gas injection pipe 20 and the reaction gas exhaust pipe 30. The same components are denoted respectively by the same reference symbols. With the hot gas dissociation method that is used with the arrangement of FIG. 6, reaction gas is brought into contact with a heater (heating/catalyzing means) 26 made of a wire of tungsten, molybdenum, tantalum, Kanthal (trade name: available from Gadelius AB) or iridium which may or may not be coated with Al₂O₃ (to be referred to as “tungsten heater 26” hereinafter) to produce a reaction gas dissociation phenomenon as described above in “Related Background Art” and subsequently inject reaction gas through the injection holes 23 for batch processing. The internal pressure of the low pressure section 20b is preferably 1 to 20 Pa.

Thus, a system that can achieve the second through fourth objects of the invention can be realized by using the structure of the system of FIG. 3 and modifying it in a manner as illustrated in FIG. 6. Note, however, the following points have to be taken into consideration.

(a) When the tungsten heater 26 and the wafers 3 are separated from each other by a short distance and the reaction temperature is low, the heater 2 (heating/catalyzing means) is not necessary because the wafers 3 can be heated to reaction temperature by the tungsten heater 26.

(b) The oxidizing agent and the gas other than the oxidizing agent need to be injected separately from the respective pipe bodies 20₍₁₎, 20₍₂₎ in order to achieve the third object of the invention.

(c) One, two or more than two wafers are processed by thermally dissociating etching gas for removing native oxide film in order to achieve the second object of the invention.

The reaction conditions that has to be satisfied when a hot heating medium such as W is used include the following.

(1) etching of Si, SiO₂, SiN using NF₃, SF₆, CHF₃:

diluted medium: He, electrically energized heating temperature: 2,400° C., pressure: 67 Pa, NF₃ flow rate: 70 sccm (as reported at the above cited Japan Society of Applied Physics).

(2) CVD of undoped hydrogenated microcrystalline Si:

SiH₄ flow rate: 2 to 15, heater area: 3 to 50 cm², gas pressure: 0.1 to 13 Pa, substrate temperature: 200 to 300° C., filament temperature: 1,500° C., W filament surface area: 4 cm², (Extended Abstract of the International Pre-workshop on Cat-CVD (Hot-Wide CVD) Process, 1999, 9, 29, Ishikawa Hitech Center, p. 55).

(3) amorphous Si:

heater temperature: 1,500 to 1,900° C., SiH₄ flow rate: 10 to 20 sccm, H₂ flow rate: 10 to 40 sccm, heater power: 100 to 600 W, heater area: 5 to 30 cm², gas pressure: 0.1 to 13 Pa, substrate temperature: 150 to 300° C. (Extended Abstract, 1st International Conference on Cat-CVD (Hot-Wide CVD) Process, 2000, 11, 14-17, Kanazawa City).

(4) poly-Si:

heater temperature: 1,500 to 1,900° C., SiH₄ flow rate: 0.5 to 10 sccm, H₂ flow rate: 0 to 200 sccm, heater power: 800 to 1,500 W, heater area: 10 to 60 cm², gas pressure: 0.1 to 40 Pa, substrate temperature: 300 to 450° C. (same as (3)).

(5) SiNₓ:

heater temperature: 1,500 to 1,900° C., SiH₄ flow rate: 0.5 to 5 sccm, NH₃ flow rate: 50 to 200 sccm, heater power: 300 to 800 W, heater area: 5 to 30 cm², gas pressure: 0.1 to 13 Pa, substrate temperature: 200 to 300° C. (same as (3)).

(6) ashing of resist:

H₂O, O₂ gas (as reported at the above cited Japan Society of Applied Physics).

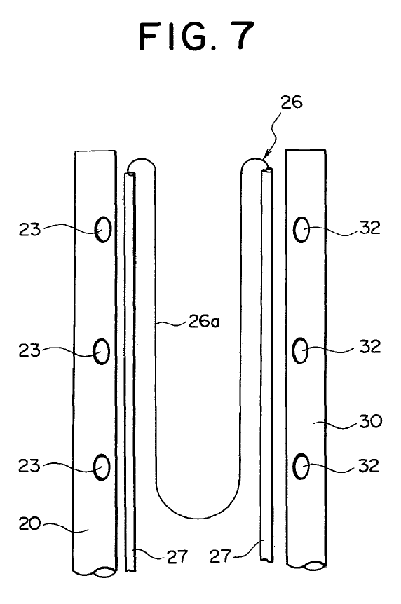

FIG. 7 is a schematic cross sectional view of a tungsten heater that can be used for the purpose of the invention and whose profile and arrangement are different from those of FIG. 6. The tungsten heater 26 is arranged between the reaction gas injection pipe 20 and the wafer holding jig. The tungsten heater 26 is guided in a sleeve 27 such as a quarts tube and then extended to the outside of the sleeve 27 to show a U-shaped profile in a hot section that is necessary for the reaction (26a). Reaction gas injected from the injection holes 23 is brought to contact with the tungsten heater 26a and subsequently forms a film on the wafers. In the sleeve 27, a gap is formed between the tungsten heater 26 and the sleeve 27. Gas such as N₂ or NH, may be made to flow through the gap in order to protect the tungsten heater 26. The tungsten heater 26 may be made to show a larger diameter in the sleeve 27 than at the outside of the sleeve 27.

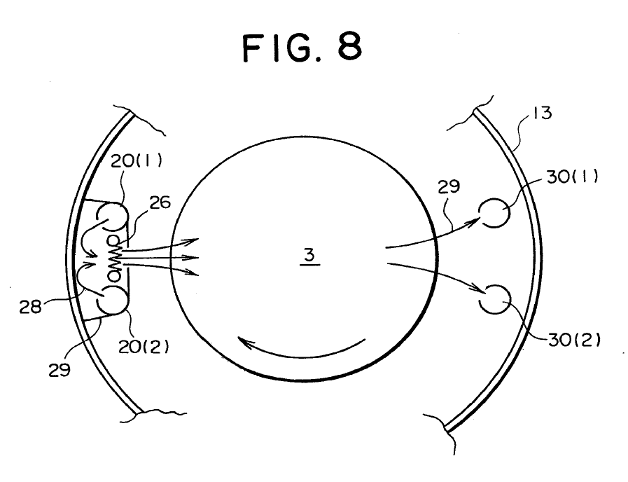

FIG. 8 is a schematic transversal cross sectional view of a vertical type furnace whose profile and arrangement are different from those of FIG. 6 and those of FIG. 7. The substrate holding jig is not shown in FIG. 8. The tungsten heater 26 is arranged between a pair of parallel pipe bodies 20₍₁₎, 20₍₂₎ of the reaction gas injection pipe 20 and adapted to heat and dissociate gas 28, which may typically be silane. Then, it supplies reaction gas that is obtained by dissociation toward the wafers 3. A block plate 29 is arranged to focus the flow of reaction gas produced by dissociation on the tungsten heater 26 and the wafers 3.

Beside the parallel pipe bodies 20₍₁₎, 20₍₂₎, a separate oxidizing agent injection pipe may be arranged at an appropriate position in the furnace in order to grow SiO₂ film.

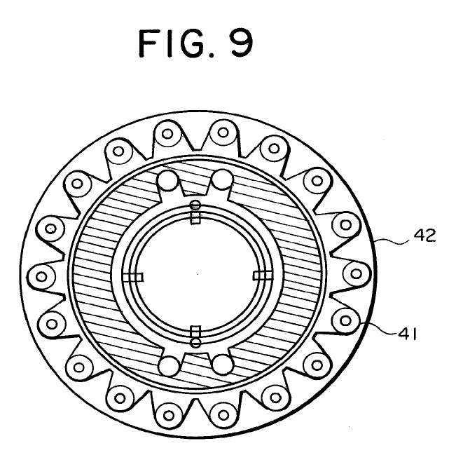

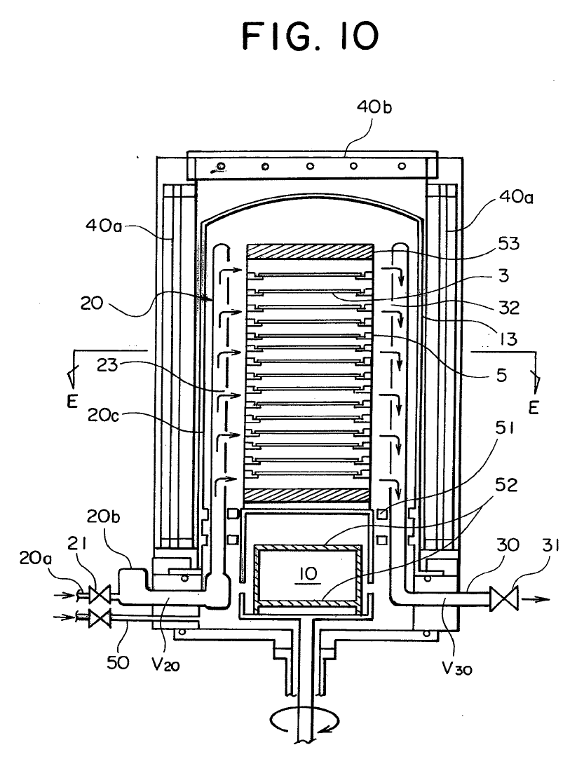

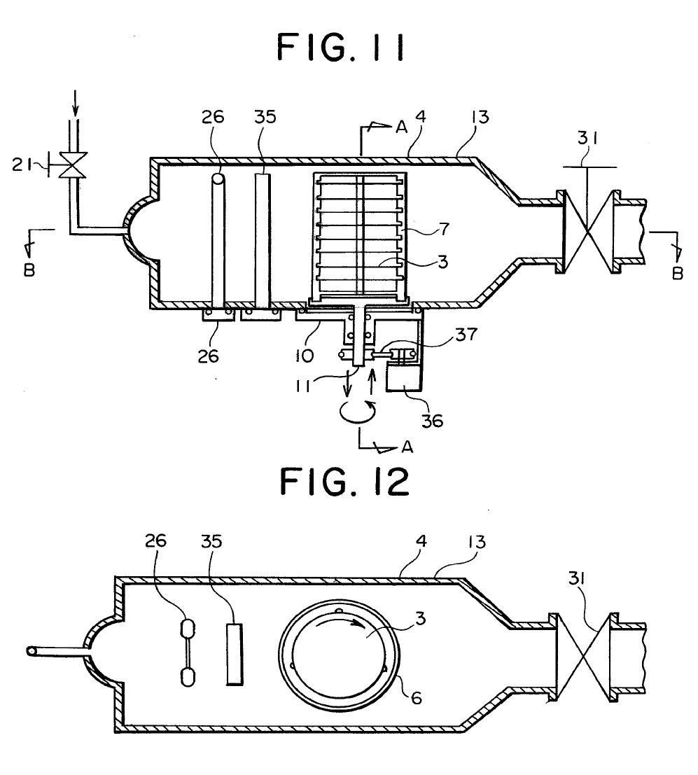

FIGS. 9 and 10 schematically illustrate an arrangement of lamp heating suited for a reaction conducted at a temperature range below that of 350 to 450° C., particularly at a temperature range between 150 and 300° C., in order to achieve the first object of the invention. Note that only the positions of current meters V₂₀, V₃₀ are shown.

In FIGS. 9 and 10, the components same as those of FIGS. 3 and 4 are denoted respectively by the same reference symbols. In FIGS. 9 and 10, reference symbol 40a denotes rod-shaped heating lamps arranged circularly and reference symbol 41 denotes a reflector panel coated with gold (Au) foil, whereas reference symbol 42 denotes a jacket. Cooling water is made to flow between the reflector panel 41 and the jacket 42. Reference symbol 40b denotes a winding lamp heater on the ceiling. Additionally, a purge gas injection pipe 50 for driving out gas in the furnace after the treatment and a separator 51 for protecting a lower part against heat in the furnace are arranged.

A reflector panel 52 is arranged in the base section 10 in order to reflect heat in the furnace and improve the uniform temperature distribution in the reaction space. Additionally, a top facet quart plate 53 is arranged above the uppermost wafer 3 to raise the hotness of the reaction space.

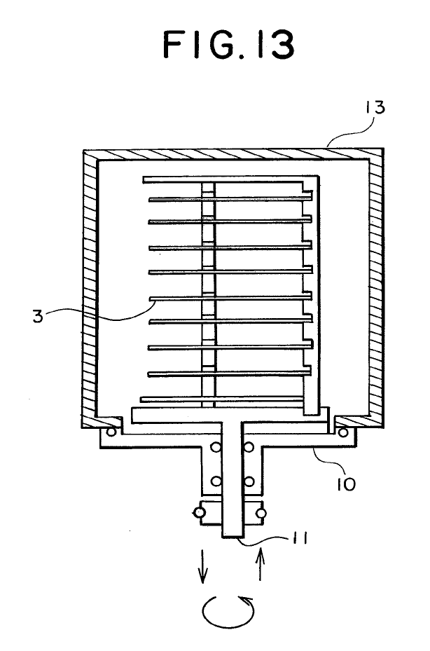

FIGS. 11 through 13 schematically illustrate another embodiment of semiconductor device manufacturing system suited for etching native oxide film and adapted to achieve the second object of the invention. In FIGS. 11 through 13, the components same as those of FIGS. 3 and 4 are denoted respectively by the same reference symbols. Note, however, that the reaction gas injection pipe 20 and the reaction gas exhaust pipe 30 are arranged in parallel with each other in a transversal direction and the reaction tube 13 and the pipes 20, 30 are made of aluminum.

Aluminum reacts with N₂, H₂ and NF₃ to form a stable and inactive film and hence can minimize the production of particles. Additionally, since NF₃ is dissociated and activated by the tungsten heater 26, its consumption rate is low.

The tungsten heater 26 shows a profile of a large number of tightly arranged W-shaped patterns as viewed in the direction of gas flow. The rate of reaction of removing native oxide film by excited NF₃ remarkably falls at 60° C. as pointed out earlier and therefore it is necessary to protect the wafers 3 from being heated to such a temperature level by the tungsten heater 26. A light shield plate 35 is arranged between the tungsten heater 26 and the substrate holding jig 6 in order to protect the wafers 3 against being heated by radiation of heat. On the other hand, a gap is left between the top section of the light shield plate 35 and the inner wall of the reaction tube 13 so that excited NF₃ may get to the wafers 3 by way of the gap. Preferably, the light shield plate 35 has a water cooling structure in the inside so that it may operates as jacket. All the wafers 3 are driven to rotate as the rotary force of the motor 36 is transmitted to the lower center shaft 11 by way of a gear 37.

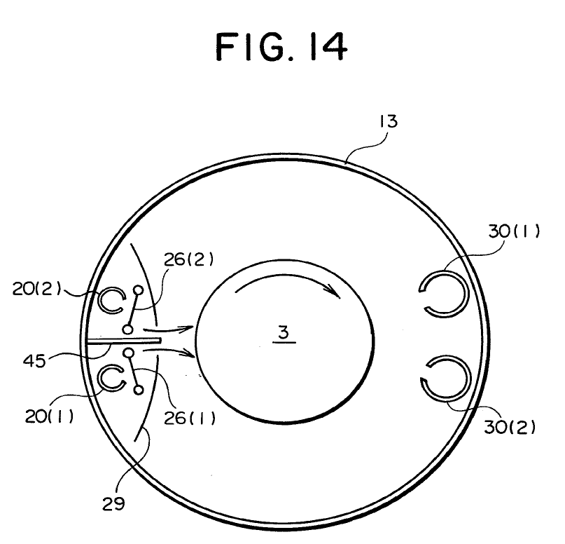

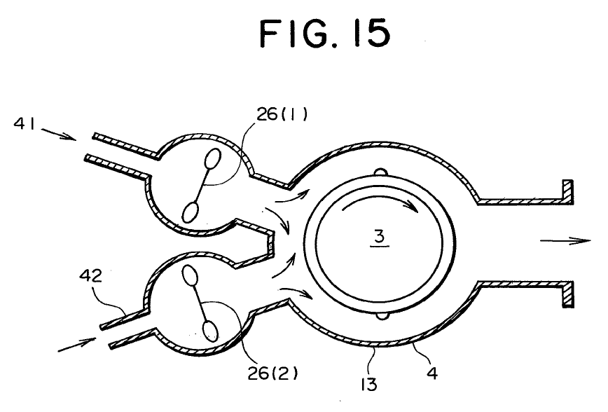

FIG. 14 is a schematic view of another system designed to achieve the fourth object of the invention. It is a cross sectional view similar to that of FIG. 8.

In FIG. 14, reference symbol 20₍₁₎ denotes an injection pipe for injecting gas other than an oxidizing agent, or SiH₄ gas for instance, reference symbol 20₍₂₎ denotes an injection pipe for injecting an oxidizing agent, or O₂ gas for instance, and reference symbol 26₍₁₎ denotes a tungsten heater, while reference symbol 26₍₂₎ denotes an iridium heater and reference symbol 45 denotes a block plate for preventing SiH₄ and O₂ from being mixed with each before dissociation.

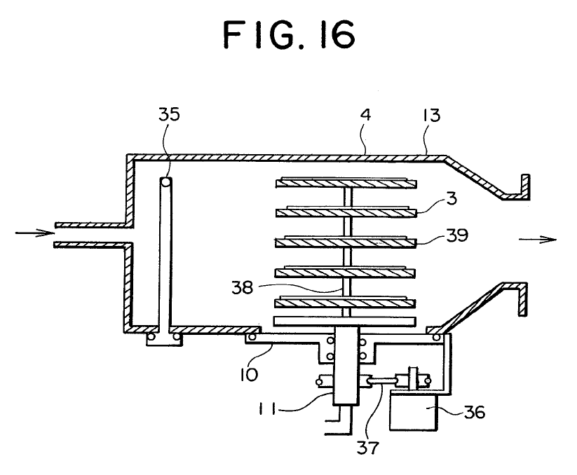

FIGS. 15 and 16 schematically illustrate still another embodiment designed to achieve the fourth object of the invention. The components same as those of FIGS. 11 through 14 are denoted respectively by the same reference symbols. This system is characterized in that wafers 3 are held not by a grooved column by respective susceptors 39 that are stacked and rigidly secured to a rotary shaft 38. A gas injection pipe 41 for injecting gas other than an oxidizing agent and an oxidizing agent injection pipe 42 are branched from the reaction tube 13.

The iridium heater 26₍₂₎ of the second embodiment is replaced by a remote plasma generator using a 2.45 GHz microwave.

What is claimed is:

1. A system for manufacturing a semiconductor device, comprising:
a substrate holding jig adapted to removably arranging one or more semiconductor substrates in a reaction tube, said substrates including or not including dummy wafers;
a heating means annexed, if necessary, to said reaction tube in order to heat the semiconductor substrates;
a first gas injection means for injecting a first gas other than an oxidizing agent into the reaction tube, said first gas injection means being formed by a tube that is extended axially in the reaction tube and is provided with injection holes for the first gas at a lateral wall portion thereof;
a first heating/catalyzing means disposed in the first gas injection means for dissociating the first gas before or after injecting gas from the first gas injection means;
a second gas injection means for injecting a second gas of an oxidizing agent into the reaction tube, said second gas injection means being formed by an another tube that is extended axially in the reaction tube and is provided with injection holes for the second gas at a side portion thereof, the second gas and the heated and catalyzed first gas being mixed with each other in the reaction tube; and
an exhaust means for exhausting the mixed first and second gases to an outside of the reaction tube.

2. A system for manufacturing a semiconductor device, comprising:
a substrate holding jig adapted to removably arranging one or more semiconductor substrates in a reaction tube, said substrates including or not including dummy wafers;
a heating means annexed, if necessary, to said reaction tube in order to heat the semiconductor substrates;
a first gas injection means for injecting a first gas other than an oxidizing agent into the reaction tube, said first gas injection means being formed by a tube that is extended axially in the reaction tube and is provided with injection holes for the first gas at a lateral wall thereof;
a first heating/catalyzing means disposed in the first gas injection means for dissociating the first gas before or after injecting gas from the first gas injection means;
a second gas injection means for injecting a second gas of an oxidizing agent into the reaction tube, said second gas injection means being formed by an another tube that is extended axially in the reaction tube and is provided with injection holes for the second gas at a side portion thereof;
a second heating/catalyzing means of iridium vanadium or an Fe—Cr—Al type electric resistor alloy for dissociating the second gas before or after injecting gas from the second gas injection means, the heated and catalyzed first gas and second gas being mixed with each other in the reaction tube; and
an exhaust means for exhausting the mixed first and second gases to an outside of the reaction tube.

3. The system according to claim 2, wherein said first and second gas injection means are arranged in parallel with each other.

4. A semiconductor device manufacturing method of manufacturing a semiconductor device, comprising:
using a semiconductor device manufacturing system according to claim 1 to manufacture the semiconductor device.

5. A semiconductor device manufacturing method of manufacturing a semiconductor device, comprising:
using a semiconductor device manufacturing system according to claim 2 to manufacture the semiconductor device.
